(19) United States
(12) Patent Application Publication
(10) Pub. No.: US 2021/0400817 A1
(43) Pub. Date: Dec. 23, 2021

(54) METHOD AND APPARATUS FOR THE POST-MANUFACTURING ADJUSTMENT OF THE CHARACTERISTIC IMPEDANCE OF PCB TRACES CARRYING HIGH-SPEED DATA SIGNALS

(71) Applicant: Mellanox Technologies, Ltd., Yokneam (IL)

(72) Inventors: Boaz ATIAS, Maale Adumim (IL); Alon RUBINSTEIN, Kfar Yona (IL); Elad MENTOVICH, Tel Aviv (IL); Anna SANDOMIRSKY, Nesher (IL); Alexei STRASHKO, Rosh ha-Ayin (IL)

(21) Appl. No.: 16/906,016

(22) Filed: Jun. 19, 2020

(51) Int. Cl. H05K 3/14; G01R 27/16

(52) U.S. Cl. CPC H05K 3/143; G01R 27/16

(57) ABSTRACT

A method for adjusting the value of the characteristic impedance Zo of a microstrip transmission line printed on an outer layer of a printed circuit board (PCB) comprises performing a post-manufacturing process directly on the artwork of a production PCB.

### FIELD OF THE INVENTION

The present invention relates to Printed Circuit Boards (PCB) designed to operate at high frequencies and capable of carrying high-speed data signals. More particularly, the invention relates to a method and apparatus for fine-adjusting the value of the characteristic impedance of microstrip transmission lines etched on the outer layers of a multilayer PCB, in order to compensate for the tolerances related to the manufacturing process.

### BACKGROUND OF THE INVENTION

In the design of systems adapted to process high speed data, and in particular in electro-optical sub-systems, whenever it is required to transfer an electrical signal between a source and a load element over a physical path the length of which is not negligible as compared to the signal wavelength, in order to preserve the signal integrity the transfer must be accomplished over a transmission line. In particular, when the sub-system consists of circuits built on a PCB, in the vast majority of cases the transmission lines are realized by means of metallic structures printed on the outer layers of the PCB using copper-etching processes, and are known as “microstrip transmission lines” (hereinafter “microstrip”). A microstrip consists of a flat conductor suspended over a ground plane. The conductor and the ground plane are separated by a dielectric layer. Every microstrip exhibits a characteristic parameter denoted as its “characteristic impedance” denoted in all that follows by the symbol Zo. A microstrip may operate in standalone configuration, or may be electromagnetically coupled to another microstrip by placing both lines in physical proximity to each other. A simplified schematic picture of a microstrip structure built on a PCB is shown in FIG. 1. The figure shows some of the critical physical parameters that determine the value of the characteristic impedance Zo, and an approximate formula (known as Wheeler's formula) for computing Zo. Moreover, other factors such as an uneven shaping of the metallic trace, or a dielectric coating applied on top of the microstrip trace, affect the value of Zo. However, the most critical parameter is the microstrip width W shown in FIG. 1. As the dimension W is made wider, the characteristic impedance Zo decreases. Coated microstrips are similar to the uncoated version, except that the metallic trace is covered by a dielectric material such as a Solder Mask (SM). This coating can lower the characteristic impedance Zo by several percent depending on the type and thickness of the coating. Detailed design guidelines accounting for width and coating, as well as for multiple additional factors, are provided in the standard IPC-2141A: Design Guide for High-Speed Controlled Impedance Circuit Boards. From FIG. 1 it is apparent that even an approximate analytic estimate of Zo is a very complex task, and in practice, the value of Zo is estimated by means of computer simulation programs such as the one developed by Polar Instruments Ltd. (https://www.polarinstruments.com/), which has been used in the illustrative examples hereof, and the user interface of which is exemplified in FIG. 4 for two coated microstrip lines with mutual coupling. FIG. 6 is an exemplary simulation of the dependence of the characteristic impedance on the microstrip width. In high-frequency applications, the accuracy of the value of the characteristic impedance is a key factor in limiting wave reflections and power losses, that occur whenever the value of Zo is not accurately matched either to the output impedance of the signal source or to the input impedance of the load element, and in determining the frequency and time domain response of the transmission lines, which in turn critically affect the signal integrity and the overall performance of the system. When manufacturing a PCB, the tolerances in the copper-etching process result in random deviations of the order of 5% in the value of the characteristic impedance Zo of the microstrip lines, with respect to the predicted figures obtained in the design stage. The deviation in the value of Zo from the predicted value depends on the parameters of the manufacturing process, and is not known a priori, but will remain fairly constant as long as the set-up parameters of the production process are kept constant. Thus, after running the first production lot of PCB prototypes, the value of Zo must be checked, and the microstrip dimensions must be corrected to obtain the required system performance. However, prior art methods do not provide means for performing post-manufacturing adjustments on the artwork of a production run. Therefore, the current strategy consists of checking the first prototype run, re-layout the PCB while introducing empirical corrections in the microstrip dimensions to compensate for the deviation of the value of Zo due to process tolerances, manufacturing at least a second run of prototypes with the same process set-up, re-checking, and, as often required, further introducing final layout corrections in order to obtain a final design for production purposes. The above multiple PCB re-design and prototyping requires about 3-4 months for each cycle, carrying substantial delay, cost, and effort.

It is therefore clear that it would be highly desirable to be able to provide a method that overcomes the abovementioned drawbacks of the prior art, and which allows a faster and more cost efficient designing process.

It is a purpose of the present invention to provide a method and apparatus for fine-adjusting the value of the characteristic impedance of microstrip transmission lines printed on the outer layers of a multilayer PCB stack-up, by means of post-manufacturing processes that can be performed directly on the artwork of a production PCB, thus saving the need for multiple re-design cycles and prototype runs.

It is a further object of the invention to provide a method which allows sequentially applying multiple corrections to the same physical PCB, and to carry out repeated adjustment and check of the characteristic impedance on the same PCB in a short time, thus ending up with a more precise design to be used for production purposes.

Other characteristics and advantages of the invention will become apparent as the description proceeds.

### SUMMARY OF THE INVENTION

The invention relates to a method for adjusting the value of the characteristic impedance Zo of a microstrip transmission line printed on an outer layer of a printed circuit board (PCB), comprising performing a post-manufacturing process directly on the artwork of a production PCB. In one embodiment, the width of the microstrip is designed taking into account the tolerances of the copper-etching process, so to yield a production value of Zo which is larger than the target value.

According to another embodiment, the value of Zo on at least one sample out of a production lot of PCBs is measured, and then the microstrip trace on the PCB is coated with a suitable dielectric material of controlled thickness and width, for example, is a solder mask, and the value of Zo is corrected and measured, until Zo is reduced to the target value.

According to yet another embodiment of the invention the value of Zo on at least one sample out of a production lot of PCBs is measured, and then the microstrip trace on the PCB is made wider by means of a controlled metal deposition so that the value of Zo is corrected and measured, until Zo is reduced to the target value. In some embodiments correction procedures using both dielectric material, and metal deposition, are applied to the same PCB. The correction procedures can also be repeatedly applied to the same PCB so to iteratively refine the adjustment of the value of Zo.

The resulting dimensions of the controlled thickness and width of the dielectric material, and/or the resulting dimensions of the controlled add-on width of the metal deposition, and/or the correction parameters resulting from the correction procedures, can thus set-up in a post-manufacturing correction process that can be applied to the whole production lot of PCBs.

Also encompassed by the invention is a PCB comprising a microstrip trace which is coated with a material of controlled thickness and width, adapted to bring the value of Zo to a target value.

As explained herein, the material of controlled thickness can be for instance a dielectric material, such as a solder mask, or a deposed metal, or both.

The invention also encompasses a PCB comprising a microstrip trace, the width of which was adjusted by adding a controlled amount of material adapted to bring the value of Zo to a target value.

### BRIEF DESCRIPTION OF THE DRAWINGS

In the drawings:

FIG. 1 is simplified schematic picture of a microstrip structure built on a PCB;

FIG. 2 is the data sheet of the PCB material Roger 1200, used in the illustrative embodiment;

FIG. 3 is a Flow-Chart describing the PCB production process;

FIG. 4 is a snapshot of the user interface of the simulation program developed by Polar Instruments Ltd., and used in the illustrative example;

FIG. 5 is a snapshot of the top layer of an exemplary PCB including microstrip traces;

FIG. 6 is a simulation of the dependence of the characteristic microstrip impedance Zo on the trace width W, used in the illustrative example;

FIG. 7 is an eye pattern of the illustrative example for the Zo=100Ω matched;

FIG. 8 is an eye pattern of the illustrative example for Zo=70Ω;

FIG. 9 is an eye pattern of the illustrative example for Zo=130Ω;

FIG. 10 is a plot of the insertion loss (IL) of the microstrip in the illustrative example;

FIG. 11 is a plot of the return loss (RL) of the microstrip in the illustrative example;

FIG. 12 is a plot of the jitter vs. Zo in a 4-PCM system;

FIG. 13 is the plot of the eye-opening amplitude vs. Zo in a 4-PCM system; and

FIG. 14 is the summary of an exemplary design process adapted to use the invention. After the basic Polar examination, deep simulations were conducted both in the Frequency and Time domain, in order to emphasize the impact on the performance of the Transmission Line Modelling (TLM).

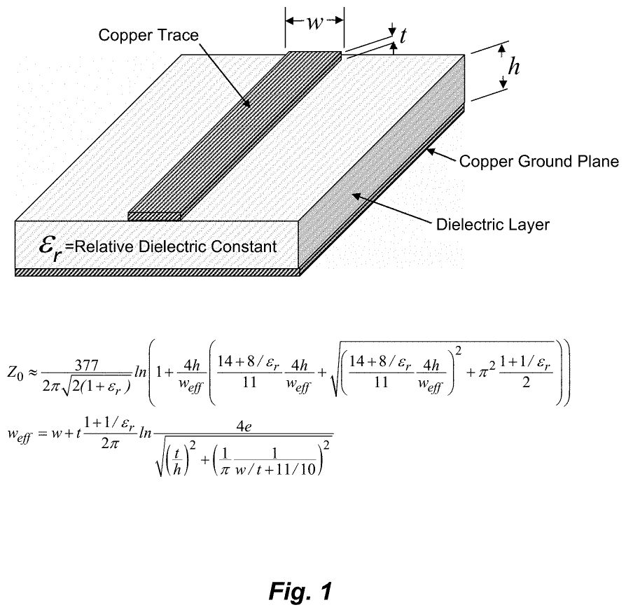

The Frequency and Time domain simulations were conducted using Q3D, HFSS 3D Layout software tools.

### DETAILED DESCRIPTION OF THE INVENTION

The invention addresses the two main disadvantages of the development approach currently employed in the industry: the investment in the design effort and prototyping cost required for refining the development by means of multiple PCB re-design cycles and multiple prototyping runs, and the consequent substantial delay in the completion of the development, resulting in a substantial increase in the time-to-market of new-developed products.

FIG. 5 shows the top layer of an exemplary PCB including microstrip traces. According to an embodiment of the invention, the width W of the microstrip traces is designed to be somewhat narrower than the design value corresponding to the optimal characteristic impedance Zo. The width W has to be designed narrow enough with respect to the average dimension that would result in production from an exact design, due the effect of the (statistically known) random tolerances of the copper-etching process, so that the actual value of Zo in the production PCBs will always turn out somewhat larger than the target value. Then, after running a production lot, the impedance Zo is measured, for example by means of a Time Domain Reflectometer (TDR), and corrected in one of the two following ways: the microstrip traces on one sample from the manufactured PCBs are either coated with a suitable dielectric material of controlled thickness and width, such as SM, or are made wider by means of a controlled Metal Deposition (MD) process, for instance, a Laser Metal Deposition (LMD). In either case the result is a controlled decrease in the value of the characteristic impedance. The correction process is repeatedly carried out and its result is checked until Zo reaches its optimal value. Then the resulting dimensions of the coating material, or the resulting add-on width of the MD, are set-up in a post-manufacturing line adapted to either performing coating or/and MD accordingly, so that the PCBs out of production may be corrected by means of an automatic post-production process, without requiring PCB redesign or additional prototyping. Since the deviation in the microstrip width W due to the copper-etching process remains fairly constant along the same production lot, the method subject of the invention results in a precise correction that yields the target value of Zo over the whole production lot of PCBs.

Hereinafter a brief description of the various stages required in order to carry out one design cycle and one prototyping run is described, and the skilled person will easily appreciate the substantial savings provided by the invention therefrom.

PCB Design Process

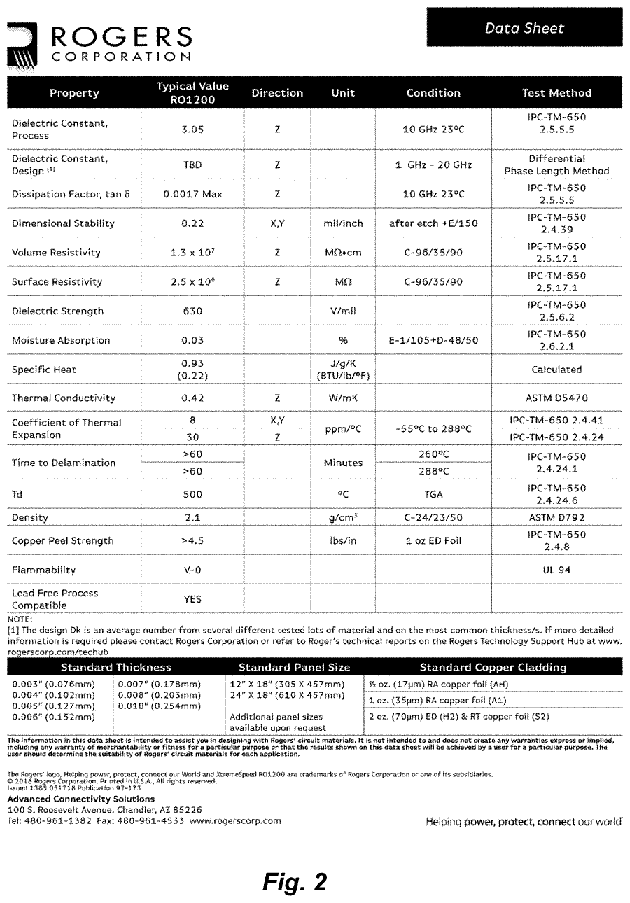

Most existing development processes proceed along the following lines:
1. Pick-up a suitable PCB material adapted to fulfill the requirements at the given operating frequency. Several materials can be used for the same purpose, and should be evaluated for suitable electrical and mechanical characteristics, as well as for cost. In the illustrative example, the base PCB material chosen was Roger 1200, which has a relative dielectric constant εᵣ=3.05, and whose data sheet is shown in FIG. 2;
2. Design the trace geometry of the various microstrips to accommodate the various impedance matching requirements;
3. Simulate the topology at pre-layout stage in order to validate the topology;
4. Build the topology with the cad tool and create a PCB design;
5. Perform a post layout simulation in order to validate the design before building the first prototype;
6. Manufacture of the first prototype of the PCB;
7. Validate the PCB under lab conditions and test the fully-assembled board functionality;
8. If any issue is found following the testing and measurements, perform a second round of layout corrections;
9. Perform a second round of post layout simulation in order to validate the layout corrections;
10. Manufacture of the second prototype based on the corrected PCB;
11. Validate the corrected PCB under lab conditions and test the fully-assembled board functionality;
12. If the validation of the corrected PCB is successful, then set-up the production line with the corrected design data and start production, else go back to step 8.

PCB Prototype Manufacturing Process

Most PCB prototype manufacturing runs require the following steps for each run:
1. The design group generates the PCB GERBER files (the files required to set-up the PCB manufacturing machinery) and hands them over to the engineering department;
2. The engineering department prepares the manufacturing documentation;
3. Production engineering prepares the multilayer PCB stack-up based on the row material in hand;
4. Production engineering prepares the copper layers for etching, by adding some thickness to the traces in order to compensate for the etching process and meet the impedance requirements;
5. Based on the GERBER files a photo resist process starts and coats the copper before the etching process, so only the coated traces are left;
6. The PCB panel enters the etching process and the traces reach their final thickness;
7. The above process is carried out for all PCB layers and then the circuit is laminated (In multi-layer boards, the layers of material are laminated (joined together) in a stack-up topology under extreme temperature and pressure);
8. Some additional processes, such as component symbols printing, are conducted to finalize the PCB.

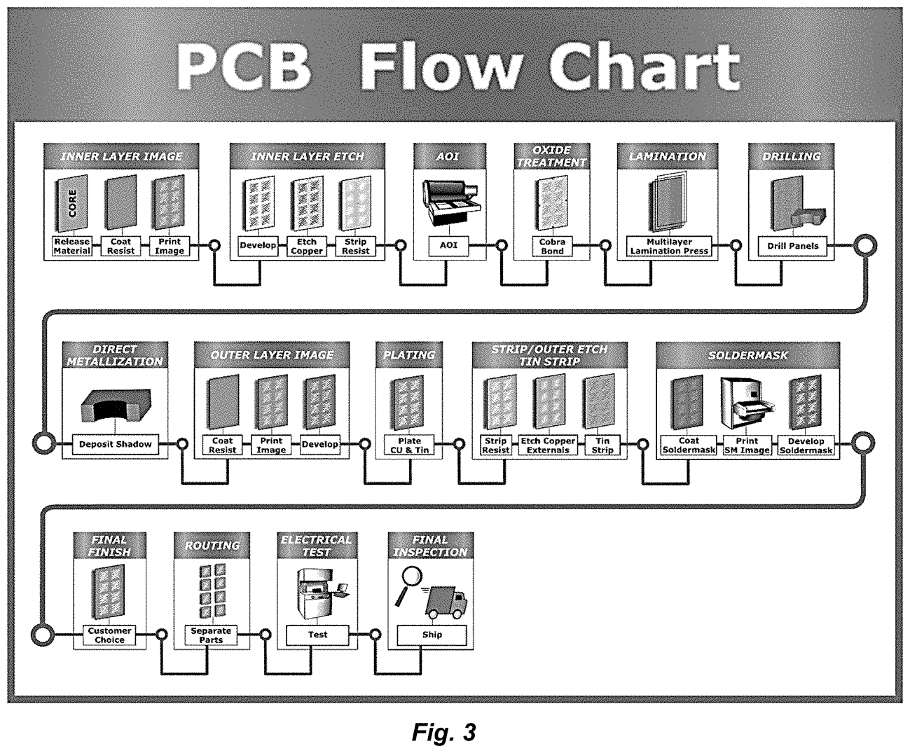

FIG. 3 shows a Flow-Chart describing the above PCB production process

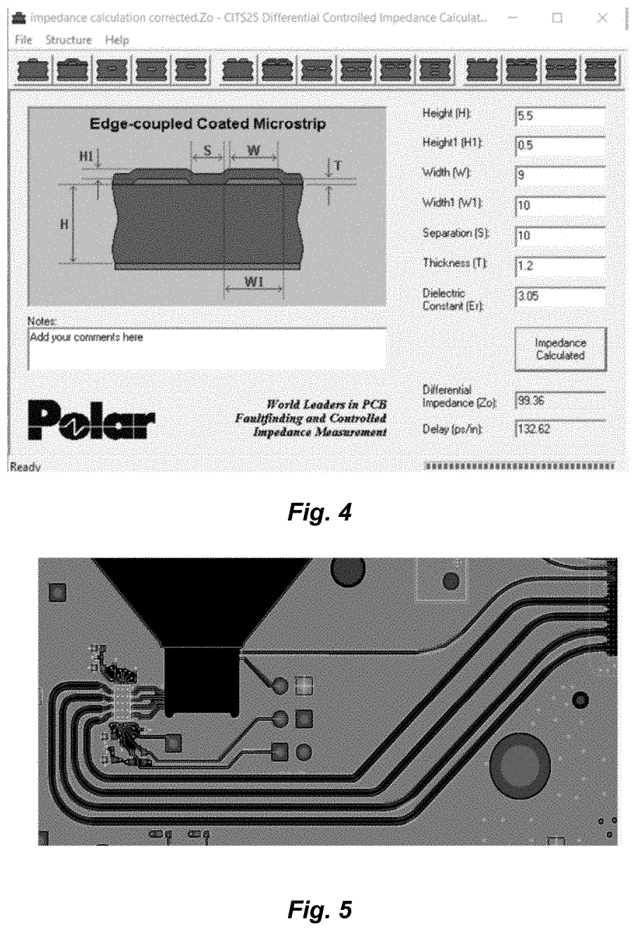

For clarity and ease of understanding, the method and apparatus of the invention will now be described with reference to an illustrative example. The computer program used for the design in the example is the “Polar” simulation of Polar Instruments Ltd., which is a commercial program used in actual product design, and the user interface of which is shown in FIG. 4.

The Scenario

In the following example, the tolerance of the copper-etching process used in production, is known to result in a microstrip width W that has a deviation ΔW of up to ±5% with respect to the target value Wo. When manufacturing a newly designed PCB, the deviation ΔW will remain fairly constant within the same production lot, however, the actual width W out of production is not known a-priori, and will be in the range 0.95Wo≤W≤1.05Wo. When manufacturing many unrelated production lots (i.e. at different times, with different machines, etc.), the deviation ΔW measured across different lots is a random variable which, for ease of understanding, is reasonably assumed to be uniformly distributed over the ±5% range with zero mean. Therefore, although each production lot will yield a different value of W (within the ±5% range), the average value of W over different production lots will be equal to the target value Wo. The present example assumes that the production line includes machinery capable to perform a LMD metal deposition process.

### An Embodiment of the Invention

According to an embodiment of the invention, as applied to the present example, the design value Wdes of the microstrip width is set to be 5% below the target value Wo, namely Wdes=0.95Wo.

It follows from the above description, that the resulting width W out of a production lot will exhibit a width 0.95Wdes≤W≤1.05Wdes, from which, by substituting Wdes=0.95Wo it follows that 0.95(0.95Wo)≤W≤1.05(0.95Wo), namely, this will always obtain 0.9Wo<W<Wo. Then, in order to increase the value of W to the target value Wo (and therefore to reduce the characteristic impedance to the target value Zo), one should increase the width W of the microstrip by adding at most 10% width to the trace using a LMD process, which can be done in an iterative way, repetitively adding a small metal width to the trace, and then measuring the characteristic impedance Zo using, for instance, a TDR, until Zo reaches the target value. Then the value of the LMD add-on width, is set-up in the LMD post-manufacturing line, and the LMD process is carried out on the whole PCB production lot.

The Design

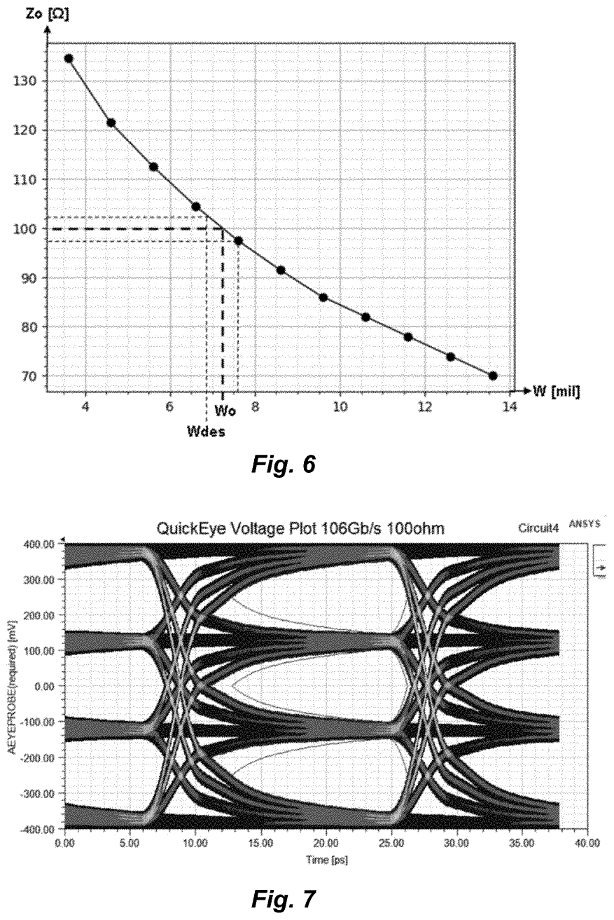

The dependency of the characteristic impedance Zo as a function on the trace width W is obtained, according to one embodiment of the invention, using the “Polar” simulation as shown in FIG. 6. The figure also shows the target trace width Wo≈7.2 [mil] corresponding to the target impedance Zo=100[Ω], and the design trace width Wdes≈6.8 [mil] whose value is 5% below Wo.

The Impact on System Performance

To better appreciate the substantial advantages of the invention, as shown in the illustrative example, it is assumed that the assembled PCB operates as part of an electro-optical system running data symbols through a microstrip at 53 Giga-Baud using 4-level PCM modulation, corresponding to a data rate of 106 Gbit/sec. The impedance of the load into which the microstrip should deliver the signal is fixed at the value Rload=100Ω.

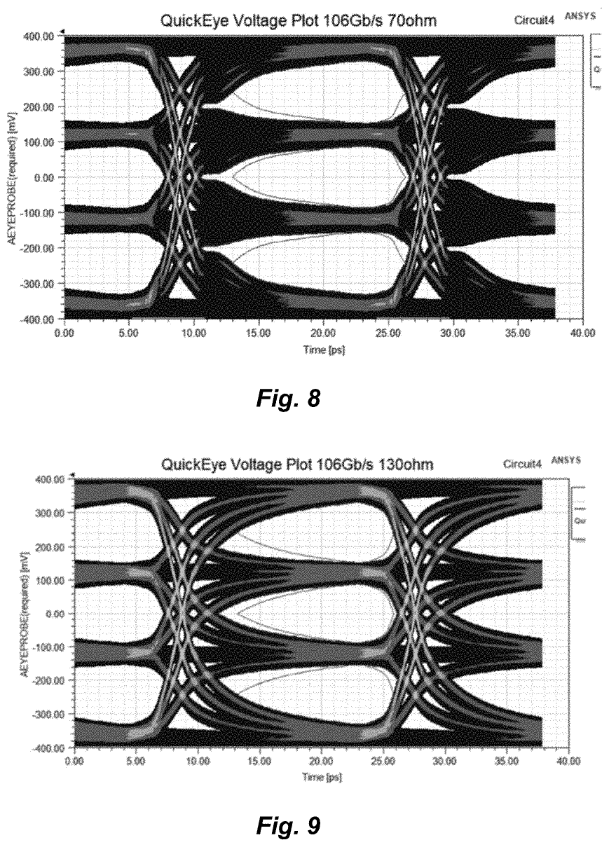

The system performance is estimated using a 4-level “eye pattern”, which is a time-domain diagram in which a signal consisting of digital symbols, each of amplitude equal to one of 4 possible levels, is repetitively sampled on the load impedance Rload placed at the end of the microstrip, during consecutive time frames of identical duration, and the sampled values in each time frame, are superimposed and displayed on the vertical axis of the diagram, while the time sweep is triggered by the symbol rate, and displayed on the horizontal axis, which results in the “eye-like” picture. Several measurements on the eye pattern are used to estimate the probability of mistakenly recognizing the wrong level for a symbol value, thus decoding erroneous data. However, a general impression of the quality of the signal and the probability of error can be obtained by just looking at the shape of the eye. If the eye is “wide open”, as seen in the eye pattern of FIG. 7 where the microstrip impedance is Zo=100Ω, namely, is “matched” to the load impedance Rload=100Ω, there is only a small probability of decoding the wrong PCM level in presence of noise, because the 4 PCM levels are well separated. However, as the value of Zo deviates from the value of Rload, the eye becomes more and more “closed”, and the probability of decoding a wrong symbol increases, as seen in FIG. 8 and FIG. 9 where, to better emphasize the effect, the microstrip impedance has been substantially mismatched, setting Zo=70Ω and Zo=130Ω respectively.

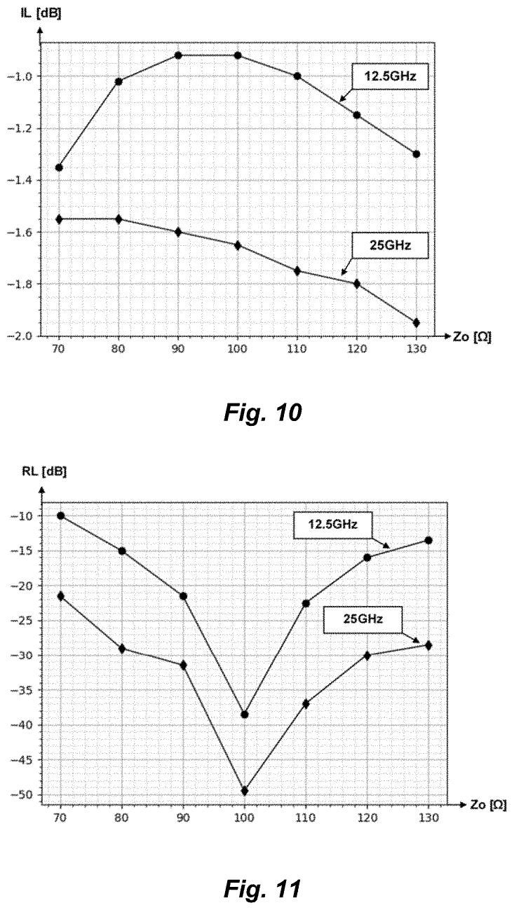

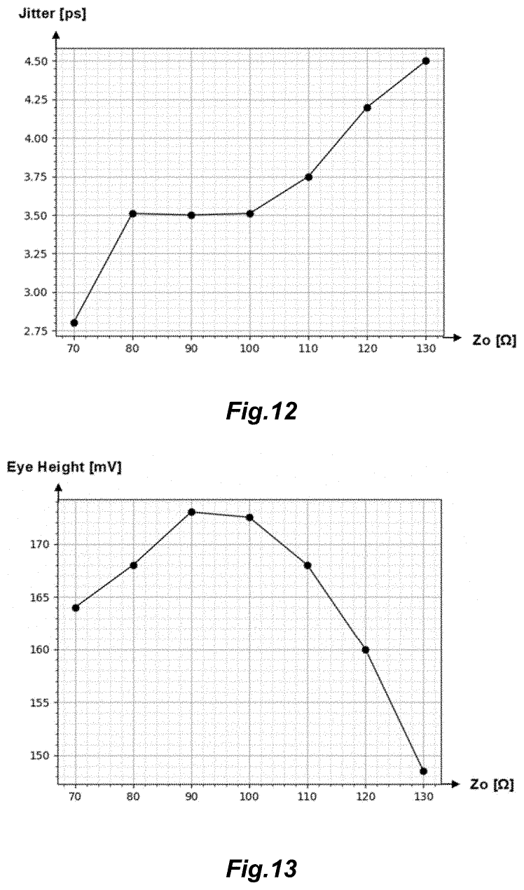

In order to further illustrate how critical the effect of the microstrip impedance even for a moderate mismatch is, the Insertion Loss (IL) and the Return Loss (RL) for a microstrip terminated with Rload=100Ω are plotted as a function of the microstrip impedance, in FIG. 10 and in FIG. 11 respectively, for signals of frequency 12.5 GHz and 25 GHz. The IL is the power loss due to heat dissipation occurring because the conductivity of the metallic microstrip trace is finite, as well as because the dielectric constant of the dielectric layer has an imaginary part. The RL is the power loss due the mismatch between Zo and Rload, which causes part of the incident power to be reflected, so that not all the signal power reaches the load. FIG. 10 shows that, for a fixed frequency, the IL exhibits moderate variations of the order of 0.5 dB even under substantial mismatch, while FIG. 11 shows that RL exhibits extreme variations, of the order of 20 dB and more, as the value of Zo deviates even moderately from the value of Rload. A microstrip mismatch not only causes power losses, which degrade the signal-to-noise ratio, but also may produce phase distortion, which often results in an overall system degradation that cannot be corrected even by a substantial increase of signal power. Such phase distortion results in an uncertainty in the zero-crossing instant of the symbols, denoted as “jitter”. Although jitter may be partially compensated by means of Clock and Data Recovery (CDR) circuits, if it becomes comparable to symbol duration, it eventually results in incorrect sampling instants of the symbols. FIGS. 12 and 13 respectively, show the value of the jitter and the eye amplitude as a function of Zo in a 4-PCM system. Beside a low jitter, good operating conditions require also to simultaneously keep the eye pattern as “open” as possible. Looking at the eye amplitude shown in FIG. 13, and the jitter values shown in FIG. 12, it is apparent that fair eye opening and low jitter are simultaneously obtained only when the microstrip is well matched, namely close to Zo=100Ω.

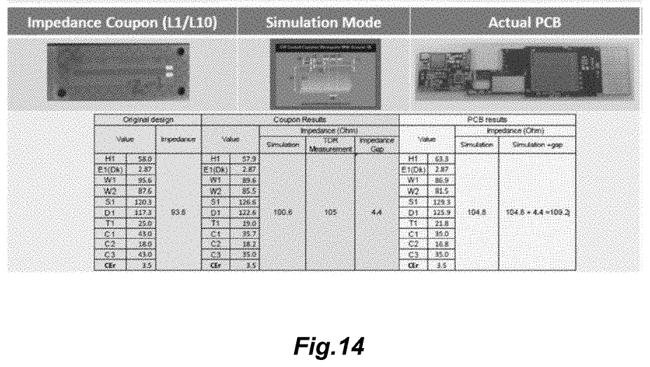

FIG. 14 shows an exemplary case of a design process adapted to use the invention:
a) First a preliminary ballpark design simulation, shown in the “original design” table, is carried out in order to determine reasonable ranges for the many parameters involved;
b) Then, the design simulation is refined to meet the target value of Zo, as shown in the “coupon results” table under the “simulation” column. Then, a “coupon PCB” is built for testing purposes. A coupon PCB is a representative test PCB containing only the critical elements, in this case, just the microstrip. The impedance Zo on the coupon is tested using a TDR setup, and the measured value is shown under the column “TDR measurement”. The discrepancy in Zo value between the simulation and the manufactured coupon is shown under the column “impedance gap”.
c) Finally, an actual PCB design is refined so that, in view of the impedance gap, the predicted outcome of the Zo value, shown under the column “simulation+gap,” yields an actual production value that can be corrected according to the invention.

All the above description and examples have been provided for the purpose of illustration and are not intended to limit the invention in any way, except as provided for in the appended claims. Many variations can be performed in embodiments of the invention. For instance, different solder masks and/or dielectric materials may be employed, alternative measurements can be used, leading to other parameters that can be used to estimate variations in the procedures, different deposition processes can be employed, all without exceeding the scope of the invention.

1. A method for adjusting the value of the characteristic impedance Zo of a microstrip transmission line printed on an outer layer of a printed circuit board (PCB), comprising performing a post-manufacturing process directly on the artwork of a production PCB.

2. A method according to claim 1, wherein the width of the microstrip is designed taking into account the tolerances of the copper-etching process, so to yield a production value of Zo which is larger than the target value.

3. A method according to claim 2, wherein the value of Zo on at least one sample out of a production lot of PCBs is measured, and then the microstrip trace on the PCB is coated with a suitable dielectric material of controlled thickness and width, and the value of Zo is corrected and measured, until Zo is reduced to the target value.

4. A method according to claim 3, wherein the dielectric material is a solder mask.

5. A method according to claim 2, wherein the value of Zo on at least one sample out of a production lot of PCBs is measured, and then the microstrip trace on the PCB is made wider by means of a controlled metal deposition so that the value of Zo is corrected and measured, until Zo is reduced to the target value.

6. A method according to claim 2, wherein correction procedures using dielectric material, and metal deposition, are applied to the same PCB.

7. A method according to claim 3, wherein the correction procedures are repeatedly applied to the same PCB so to iteratively refine the adjustment of the value of Zo.

8. A method according to claim 3, wherein the resulting dimensions of the controlled thickness and width of the dielectric material are set-up in a post-manufacturing correction process that can be applied to the whole production lot of PCBs.

9. A method according to claim 5, wherein the resulting dimensions of the controlled add-on width of the metal deposition are set-up in a post-manufacturing correction process that can be applied to the whole production lot of PCBs.

10. A method according to claim 7, where the correction parameters resulting from the correction procedures are set-up in a post-manufacturing correction process that can be applied to the whole production lot of PCBs.

11. A PCB comprising a microstrip trace which is coated with a material of controlled thickness and width, adapted to bring the value of Zo to a target value.

12. The PCB of claim 11, wherein the material of controlled thickness is a dielectric material.

13. The PCB of claim 12, wherein the dielectric material is a solder mask.

14. A PCB comprising a microstrip trace the width of which was adjusted by adding a controlled amount of material adapted to bring the value of Zo to a target value.

15. The PCB of claim 14, wherein the material a controlled amount of which was added is a deposed metal.
